(19) United States
(12) Patent Application Publication
(10) Pub. No.: US 2011/0074516 A1
(43) Pub. Date: Mar. 31, 2011

(54) PIEZOELECTRIC CERAMIC COMPOSITION, PIEZOELECTRIC CERAMIC, PIEZOELECTRIC ELEMENT, AND OSCILLATOR

(75) Inventors: Hideaki SONE, Tokyo (JP); Masakazu Hirose, Tokyo (JP); Hideya Sakamoto, Tokyo (JP); Tomohisa Azuma, Tokyo (JP)

(73) Assignee: TDK Corporation, Tokyo (JP)

(21) Appl. No.: 12/887,726

(22) Filed: Sep. 22, 2010

(30) Foreign Application Priority Data
Sep. 25, 2009 (JP) 2009-221062

(51) Int. Cl. H03B 5/32

(52) U.S. Cl. 331/158; 252/62.9 PZ

(57) ABSTRACT

A piezoelectric ceramic composition is provided which contains Perovskite oxides expressed by General Formula 1 below and an aluminum compound, and in which the content ratio of the aluminum compound to the Perovskite oxides is from 1% by mass to 11% by mass,

(Pb_{α-β-γ-δ}M1_{β}M2_{γ}Bi_{δ})[Ti_{{1-(x+y+z)}}ZrₓMn_{y}Nb_{z}]O₃ (1)

wherein in the General Formula (1), M1 represents at least one kind of element selected from the group consisting of La, Ce, Pr, and Nd, M2 represents at least one kind of element selected from the group consisting of Sr, Ca, and Ba, and α, β, γ, δ, x, y, and z satisfy the following numerical conditions:
0.96≦α≦1.01
0.03≦β≦0.07
0≦γ≦0.10
0≦δ≦0.02
0≦x≦0.24
0.02≦y≦0.04
0.03≦z≦0.08

### BACKGROUND OF THE INVENTION

1. Field of the Invention

The present invention relates to a piezoelectric ceramic composition, a piezoelectric ceramic, a piezoelectric element, and an oscillator.

2. Related Background Art

A piezoelectric ceramic composition shows a piezoelectric effect where electric polarization occurs in response to pressure from the outside and a reverse piezoelectric effect where the application of an electric field from the outside causes deformation. Thus, such a piezoelectric ceramic composition is used as a material for realizing interconversion between electrical and mechanical energy. Such a piezoelectric ceramic composition is used for various kinds of products such as oscillators (resonators), filters, sensors, actuators, ignition devices, or ultrasonic motors.

The properties of such a piezoelectric ceramic composition are improved by adding various auxiliary components to PZT (PbTiO₃—PbZrO₃ solid solution)-based and PbTiO₃-based Perovskite oxides. For example, Japanese Unexamined Patent Application Publication No. 2007-182353 proposes a technique in which resonance frequency temperature properties, heat resistance, and mechanical strength are improved by adding Al₂O₃ to PZT-based Perovskite oxides.

However, the piezoelectric ceramic composition provides different vibration modes according to the application thereof. Therefore, the proportions of constituent elements of the main component in a composition system which is suitable for each vibration mode are adjusted, and auxiliary components are added. For example, in Japanese Unexamined Patent Application Publication No. 2007-182353, investigations are made into a piezoelectric ceramic composition capable of improving the above-mentioned respective properties in a thickness-shear vibration mode, as is clear from the evaluation results of its thickness-shear mode electromechanical coupling coefficient k₁₅. On the other hand, PbTiO₃-based Perovskite oxides are attracting more attention as a piezoelectric ceramic composition for a 3rd-harmonic thickness extentional vibration mode.

### SUMMARY OF THE INVENTION

As described above, the piezoelectric ceramic composition uses different vibration modes in accordance with the purpose of use thereof. Therefore, the piezoelectric ceramic composition needs to have compositions suitable for the vibration mode. For example, the oscillation frequency of piezoelectric ceramics used for a single harmonic vibration mode of thickness-shear vibration is about 4 to 11 MHz, whereas the oscillation frequency of piezoelectric ceramics used for a 3rd-harmonic thickness extentional vibration mode is as high as 16 to 50 MHz. Therefore, particularly, when the oscillation frequency of piezoelectric ceramics used for the 3rd-harmonic thickness extentional vibration mode is 30 MHz or higher, the piezoelectric ceramics need to be made thin. As a result, a piezoelectric element can be easily broken during processing such as lapping. Accordingly, it is necessary to increase the frequency constant (fr·t) which is the product of a resonance frequency fr (Hz) and a thickness t (m) of a piezoelectric element, thus suppressing occurrence of breaking during processing.

Moreover, the piezoelectric ceramics used for the 3rd-harmonic thickness extentional vibration mode need to have not only a high Curie temperature but also a high mechanical quality factor (Qₘₐₓ) in order to enable stable oscillation at low voltages, particularly when used in a resonator.

The present invention has been made in consideration of the above circumstances. An object of the present invention is to provide a piezoelectric ceramic and a piezoelectric element having a high mechanical quality factor, a high frequency constant and a high Curie temperature and a piezoelectric ceramic composition capable of forming the piezoelectric ceramic and piezoelectric element having such properties. Another object of the present invention is to provide an oscillator which includes the above-mentioned piezoelectric ceramic, and is thus capable of performing stable oscillation under a high-temperature environment.

In order to achieve the objects, according to a first aspect of the present invention, there is provided a piezoelectric ceramic composition which contains Perovskite oxides expressed by General Formula (1) below and an aluminum compound, and in which the content ratio of the aluminum compound to the Perovskite oxides is from 1% by mass to 11% by mass,

(Pb_{α-β-γ-δ}M1_{β}M2_{γ}Bi_{δ})[Ti_{{1-(x+y+z)}}ZrₓMn_{y}Nb_{z}]O₃ (1)

wherein M1 represents at least one kind of element selected from the group consisting of La, Ce, Pr, and Nd, M2 represents at least one kind of element selected from the group consisting of Sr, Ca, and Ba, and α, β, γ, δ, x, y, and z satisfy the following numerical conditions:
0.96≦α≦1.01
0.03≦β≦0.07
0≦γ≦0.10
0≦δ≦0.02
0≦x≦0.24
0.02≦y≦0.04
0.03≦z≦0.08

According to the piezoelectric ceramic composition of the present invention, it is possible to form a piezoelectric ceramic, a piezoelectric element, and an oscillator having a high mechanical quality factor, a high frequency constant, and a high Curie temperature.

According to a second aspect of the present invention, there is provided a piezoelectric ceramic which has a sintered body made of the piezoelectric ceramic composition, and in which the particle size of the aluminum compound in the sintered body is equal to or smaller than 10 μm. This piezoelectric ceramic has a high mechanical quality factor, a high frequency constant, and a high Curie temperature.

According to a third aspect of the present invention, there is provided a piezoelectric element including a piezoelectric ceramic which has a sintered body made of the piezoelectric ceramic composition, and in which the particle size of the aluminum compound in the sintered body is equal to or smaller than 10 μm, and an electrode provided on the piezoelectric ceramic. This piezoelectric element has a high mechanical quality factor, a high frequency constant (Fr·t), and a high Curie temperature.

According to a fourth aspect of the present invention, there is provided an oscillator including the piezoelectric element. Such an oscillator can perform stable oscillation under high-temperature environment since it includes the piezoelectric element having the above-described properties.

According to the aspects of the present invention, it is possible to provide a piezoelectric ceramic and a piezoelectric element having a high mechanical quality factor, a high frequency constant (Fr·t) and a high Curie temperature and a piezoelectric ceramic composition capable of forming the piezoelectric ceramic and piezoelectric element having such properties. Moreover, it is possible to provide an oscillator which includes the above-mentioned piezoelectric ceramic, and is thus capable of performing stable oscillation under high-temperature environment.

### BRIEF DESCRIPTION OF THE DRAWINGS

FIG. 1 is a perspective view showing an oscillator according to a preferred embodiment of the present invention.

FIG. 2 is an exploded perspective view of an assembly that constitutes the oscillator shown in FIG. 1.

### DESCRIPTION OF THE PREFERRED EMBODIMENTS

In the following, preferred embodiments of the present invention will be explained in detail with reference to the drawings as necessary. In the drawings, the same reference numerals designate the same or equivalent elements, and redundant description is omitted as appropriate.

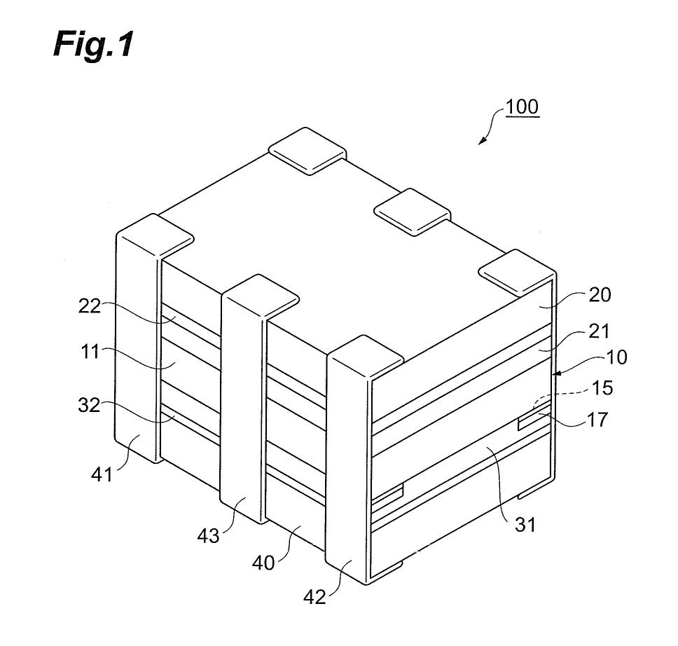

FIG. 1 is a perspective view showing an oscillator according to a preferred embodiment of the present invention. An oscillator 100 of FIG. 1 includes a piezoelectric element 10, a top board 20, a base board 40, terminal electrodes 41 to 43, a first cavity layer 21, a first sealing layer 22, a second cavity layer 31, and a second sealing layer 32.

The terminal electrodes 41 to 43 are formed in a strip shape with a predetermined distance therebetween on both side surfaces of an assembly in which the base substrate 40, the second sealing layer 32, the second cavity layer 31, a piezoelectric substrate 11, the first cavity layer 21, the first sealing layer 22, and the top board 20 are laminated in that order.

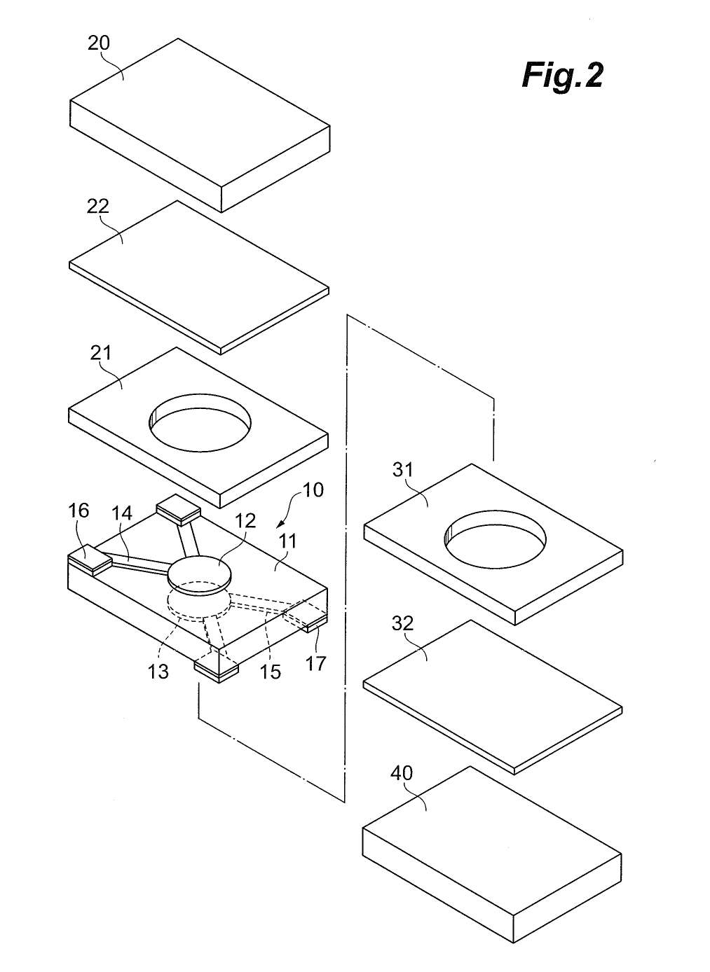

FIG. 2 is an exploded perspective view of the assembly that constitutes the oscillator shown in FIG. 1. As shown in FIG. 2, the piezoelectric element 10 includes the piezoelectric substrate 11 having a quadrangular prism shape and a first vibrating electrode 12 and a second vibrating electrode 13 which are provided at the central portions of the opposite surfaces of the piezoelectric substrate 11. A region interposed between the first and second vibrating electrodes 12 and 13 serves as a vibrating portion.

The piezoelectric element 10 has a pair of first lead electrodes 14 which is connected to the first vibrating electrode 12 and which is formed on one surface of the piezoelectric substrate 11 where the first vibrating electrode 12 is formed. The pair of first lead electrodes 14 extends from the first vibrating electrode 12 towards corners on the one surface and covers the opposing corners of the one surface. Moreover, an edge electrode 16 is provided on each of the first lead electrodes 14 covering the corners, and the edge electrode 16 is electrically connected to the first vibrating electrode 12 by the corresponding first lead electrode 14. The first lead electrodes 14 and the edge electrodes 16 are provided so as to be partially exposed to the side surface of the assembly.

Moreover, the piezoelectric element 10 has a pair of second lead electrodes 15 which is connected to the second vibrating electrode 13 and which is formed on the other surface of the piezoelectric substrate 11 where the second vibrating electrode 13 is formed. The pair of second lead electrodes 15 extends from the second vibrating electrode 13 towards corners on the other surface and covers the opposing corners of the other surface. Moreover, an edge electrode 17 is provided on each of the second lead electrodes 15 covering the corners, and the edge electrode 17 is electrically connected to the second vibrating electrode 13 by the corresponding second lead electrode 15. The second lead electrodes 15 and the edge electrodes 17 are provided so as to be partially exposed to the side surface of the assembly. The edge electrodes 16 are provided at one end of the piezoelectric substrate 11, and the edge electrodes 17 are provided at the other end of the piezoelectric substrate 11.

The first and second vibrating electrodes 12 and 13, and the first and second lead electrodes 14 and 15 can be produced by a known method and can be formed using a thin film technique such as sputtering or a thick film technique using a paste or the like.

On one surface of the piezoelectric element 10, the first cavity layer 21, the first sealing layer 22, and the top board 20 are laminated in that order. Specifically, one surface of the first cavity layer 21 is bonded to the piezoelectric element 10, one surface of the first sealing layer 22 is bonded to the other surface of the first cavity layer 21, and the other surface of the first sealing layer 22 is bonded to the top board 20. The top board 20 protects the first cavity layer 21 and the first sealing layer 22, and the strength of the oscillator 100 can be improved.

On the other surface of the piezoelectric element 10, the second cavity layer 31, the second sealing layer 32, and the base substrate 40 are laminated in that order. Specifically, one surface of the second cavity layer 31 is bonded to the piezoelectric element 10, one surface of the second sealing layer 32 is bonded to the other surface of the second cavity layer 31, and the base substrate 40 is bonded to the other surface of the second sealing layer 32. The base substrate 40 further increases the mechanical strength of the oscillator 100.

On the opposite side surfaces of the assembly assembled as shown in FIG. 2, the first, second, and third terminal electrodes 41, 42, and 43 are formed as shown in FIG. 1. These terminal electrodes can be produced by a known method and can be formed using a thin film technique such as sputtering or a thick film technique using a paste or the like.

The first terminal electrodes 41 are formed on the side surfaces of the assembly, to which the first lead electrodes 14 are exposed, and are connected to the corresponding first lead electrodes 14. The second terminal electrodes 42 are formed on the side surfaces of the assembly, to which the second lead electrodes 15 are exposed, and are connected to the corresponding second lead electrodes 15. On the other hand, the third terminal electrodes 43 are used as an earth electrode.

The oscillator 100 is used in a state of being mounted on a printed board, for example. The piezoelectric substrate 11 of this oscillator 100 is a piezoelectric ceramic made of a piezoelectric ceramic composition having particular compositions. Hereinafter, this piezoelectric ceramic composition will be described.

The piezoelectric ceramic composition of the present embodiment contains Perovskite oxides (ABO₃) expressed by General Formula 1 below as its main component.

(Pb_{α-β-γ-δ}M1_{β}M2_{γ}Bi_{δ})[Ti_{{1-(x+y+z)}}ZrₓMn_{y}Nb_{z}]O₃ (1)

In General Formula 1, M1 represents at least one kind of lanthanoid element selected from the group consisting of La, Ce, Pr, and Nd. M1 preferably includes La and may include Ce, Pr, and Nd whose ion radius is approximate to that of La³⁺.

Moreover, in General Formula 1, M2 represents at least one kind of alkaline-earth metal element selected from the group consisting of Sr, Ba, and Ca. Among these elements, Sr is preferable as M2. It should be noted that M2 is an optional element and may be not included in the Perovskite oxides.

In General Formula 1, β is in the range of from 0.03 to 0.07. If β is smaller than 0.03, the mechanical quality factor decreases. If β exceeds 0.07, the Curie temperature decreases. By controlling β so as to be in the above-mentioned range, it is possible to obtain a piezoelectric ceramic composition having a high mechanical quality factor and a high Curie temperature. From the same perspective, β is preferably in the range of from 0.035 to 0.06.

In General Formula 1, γ is in the range of from 0 to 0.1. If γ exceeds 0.1, the Curie temperature decreases, so that depolarization can occur easily when the piezoelectric element is heated. From the perspective of a piezoelectric ceramic composition having a higher frequency constant, γ is preferably in the range of from 0 to 0.07, and more preferably, in the range of from 0 to 0.05.

In General Formula 1, δ is in the range of from 0 to 0.02. If δ exceeds 0.02, the mechanical quality factor decreases. By controlling δ so as to be in the above-mentioned range, it is possible to obtain a piezoelectric ceramic composition having a high mechanical quality factor.

In General Formula 1, x is in the range of from 0 to 0.24. If x exceeds 0.24, the mechanical quality factor decreases, and the Curie temperature decreases, so that depolarization can occur easily when a piezoelectric element is heated. From the perspective of a piezoelectric ceramic composition having a higher frequency constant, x is preferably in the range of from 0 to 0.2, and more preferably, 0 to 0.15.

In General Formula 1, y is in the range of from 0.02 to 0.04. If y is smaller than 0.020, the mechanical quality factor decreases. If y exceeds 0.04, a resistivity decreases, so that polarization treatment is difficult. By controlling y so as to be in the above-mentioned range, it is possible to obtain a piezoelectric ceramic composition which can be easily polarized and has a high mechanical quality factor. From the same perspective, y is preferably in the range of from 0.024 to 0.038, and more preferably, in the range of from 0.028 to 0.036.

In General Formula 1, z is in the range of from 0.03 to 0.08. If z is smaller than 0.03, sinterability is degraded. If z exceeds 0.08, the Curie temperature decreases, so that depolarization can occur easily when a piezoelectric element is heated. By controlling z so as to be in the above-mentioned range, it is possible to obtain a piezoelectric ceramic composition which can be used at high temperatures and has good sinterability. From the same perspective, z is preferably in the range of from 0.04 to 0.08, and more preferably, in the range of from 0.05 to 0.08.

In General Formula 1, α which represents the atomic ratio (A/B) of A site to B site is preferably in the range of from 0.96 to 1.01. If α is smaller than 0.96 or exceeds 1.01, the mechanical quality factor tends to decrease. By controlling a so as to be in the above-mentioned range, it is possible to obtain a piezoelectric ceramic composition having a sufficiently high mechanical quality factor. From the same perspective, α is preferably in the range of from 0.97 to 1.00.

A numerical value (α-β-γ-δ) which represents the atomic ratio of Pb in A site is preferably in the range of from 0.8 to 0.97, and more preferably, in the range of from 0.81 to 0.96. If the numerical value (α-β-γ-δ) is smaller than 0.8, the Curie temperature tends to decrease. If the numerical value (α-β-γ-δ) exceeds 0.97, the ratio of other elements in A site becomes small, and it tends to be difficult to obtain sufficiently high Curie temperature and mechanical quality factor.

The piezoelectric ceramic composition of the present embodiment contains an aluminum compound as an auxiliary component in addition to the main component. The content ratio of the aluminum compound to the Perovskite oxides is in the range of from 1% by mass to 11% by mass. If the content ratio is smaller than 1% by mass, it is not possible to increase a frequency constant. If the content ratio exceeds 11% by mass, the ratio of the Perovskite oxides exhibiting piezoelectric properties decreases, and thus, the mechanical quality factor decreases. By controlling the content ratio of the aluminum compound so as to be in the above-mentioned range, it is possible to obtain a piezoelectric ceramic composition having a high frequency constant and a high mechanical quality factor. From the same perspective, the content ratio of the aluminum compound to the Perovskite oxides is preferably in the range of from 2% by mass to 10% by mass, more preferably, in the range of from 3% by mass to 9% by mass, and still more preferably, in the range of from 4% by mass to 8% by mass.

The aluminum compound included in the piezoelectric ceramic composition is not particularly limited, but is preferably an aluminum oxide (Al₂O₃) from the perspective of the availability of raw materials.

The piezoelectric ceramic composition may be in a form of powder and may be a sintered body, namely a structural component of a piezoelectric ceramic. It is preferable that the Perovskite oxides and the aluminum compound in the piezoelectric ceramic composition are present as particles and the particles of the aluminum compound which is used as the auxiliary component are dispersed in grain-boundary regions of the particles of the Perovskite oxides which are used as the main component.

The maximum (hereinafter sometimes referred to as maximum particle size) of the particle diameters of the aluminum compound particles in the sintered body is preferably equal to or smaller than 10 μm, more preferably, equal to or smaller than 6 μm, and still more preferably, in the range of from 2 to 6 μm. If the maximum particle size exceeds 10 μm, vibration of the piezoelectric element may be disturbed, so that it tends to be difficult to obtain a sufficiently high mechanical quality factor. If the maximum particle size is smaller than 2 μm, the frequency constant tends to decrease slightly.

In this specification, the maximum particle size of the aluminum compound particles can be calculated by observing the surface or cross-section of a sintered body made of the piezoelectric ceramic composition using a scanning electron microscope (SEM) and obtaining the maximum of the particle sizes of aluminum compound particles appearing in an image (magnification: 3500). The number of aluminum compound particles used for the particle size measurement is preferably 50 or more. When the aluminum compound particles are polyhedral shaped, the particle size of each particle can be calculated as the diameter of a circle having the same area as the area of the particle on the image.

In the oscillator 100 of the present embodiment, the piezoelectric element 10 has the piezoelectric substrate 11 made of the above-described piezoelectric ceramic composition. Therefore, it is possible to increase the frequency constant, Curie temperature, and mechanical quality factor of the oscillator 100 when the oscillator 100 is used in an oscillation circuit as an oscillator that uses a 3rd-harmonic thickness extentional vibration mode.

Next, an example of a manufacturing method of the oscillator 100 according to the present embodiment will be described. This manufacturing method includes a granulating step of granulating a raw-material powder of the piezoelectric substrate 11 which is a piezoelectric ceramic, a sintering step of subjecting this raw-material powder to press molding to form a temporary compact and calcining the compact to produce a sintered body, a polarization step of subjecting the sintered body to a polarization treatment to form the piezoelectric substrate 11, an electrode forming step of forming electrodes on the piezoelectric substrate 11 to obtain the piezoelectric element 10, a laminating step of laminating the piezoelectric element 10, the cavity layers 21 and 31, the sealing layers 22 and 32, the top board 20, and the base substrate 40 to manufacture the oscillator 100. The details of the respective steps will be described below.

In the granulating step, first, raw materials for preparing a piezoelectric ceramic composition are prepared. As the raw materials, oxides of respective elements that constitute the piezoelectric ceramic composition expressed by General Formula 1 or compounds (carbonate, hydroxide, oxalate, nitrate, or the like) which become these oxides after calcination can be used. As specific raw materials, powdered compounds such as PbO; compounds of La, Ce, Pr or Nd (for example, La₂O₃, La(OH)₃, and the like); compounds of alkaline-earth metal elements (for example, SrCO₃, BaCO₃, CaCO₃, and the like); and TiO₂, ZrO₂, MnO₂ or MnCO₃, Nb₂O₅, Bi₂O₃, and Al₂O₃ can be used.

These respective raw-material powders are weighed and wet-mixed by a ball mill or the like in the mass ratio so as to obtain a piezoelectric ceramic composition includes a Perovskite oxides having compositions expressed by General Formula 1 and an aluminum compound whose content ratio to the Perovskite oxides is in a predetermined range after calcination. Here, the average particle size of the powder of the aluminum compound (for example, Al₂O₃) is preferably in the range of from 0.1 to 7 μm, and more preferably, in the range of from 0.5 to 4 μm. If the average particle size of the aluminum compound powder exceeds 7 μm, the particle size of the aluminum compound in an obtained piezoelectric ceramic composition increases, and thus, it tends to be difficult to obtain a piezoelectric ceramic composition having a sufficiently high mechanical quality factor. On the other hand, if the average particle size of the aluminum compound powder is smaller than 0.1 μm, grain growth may take place in the sintering step, the particle size of the aluminum compound in an obtained piezoelectric ceramic composition increases, and thus, it tends to be difficult to obtain a piezoelectric ceramic composition having a sufficiently high mechanical quality factor.

In this specification, the average particle size of the raw-material powder of the aluminum compound or the like refers to the particle size (median diameter) corresponding to 50 volume % of an integrated distribution curve measured using a commercially available granulometry.

Subsequently, a raw-material mixture obtained by wet-mixing is subjected to temporary shaping to for a temporary compact, and this temporary compact is subjected to calcination. By this calcination, a calcined body containing the above-described piezoelectric ceramic composition can be obtained. The calcination temperature is preferably in the range of from 700 to 1050° C., and the calcination time is preferably in the range of from about 1 to 3 hours. If the calcination temperature is too low, a chemical reaction in the temporary compact tends to do no progress sufficiently. If the calcination temperature is too high, the temporary compact begins to be sintered, and therefore, it tends to make a subsequent grinding operation difficult. Moreover, the calcination may be carried out in the air and may be carried out in an atmosphere where the oxygen partial pressure is higher than in the air or a pure-oxygen atmosphere. Furthermore, the wet-mixed starting raw materials may be subjected to calcination as it was without forming the temporary compact.

Subsequently, the obtained calcined body is made into a slurry form, and after this slurry is finely grinded (wet-grinding) by a ball mill or the like, the slurry is dried to obtain a fine powder. A binder is added to the obtained fine powder as necessary, and the raw-material powder is granulated. As a solvent used for making the calcined body into a slurry form, water, alcohol such as ethanol, a mixture solvent of water and ethanol, or the like is preferably used. Moreover, as the binder added to the fine powder, generally used organic binders such as polyvinyl alcohol, dispersant-added polyvinyl alcohol, or ethylcellulose can be used.

In the sintering step, the granulated raw-material powder is subjected to press molding to form a compact. The pressure during the press molding is preferably in the range of from 100 to 400 MPa, for example.

Subsequently, the obtained compact is subjected to a binder removal treatment. The binder removal treatment is preferably carried out at temperature ranging from 300 to 700° C. for about 0.5 to 5 hours. Moreover, the binder removal treatment may be carried out in the air and may be carried out in an atmosphere where the oxygen partial pressure is higher than in the air or a pure-oxygen atmosphere.

After the binder removal treatment, by calcining the compact, a sintered body is obtained which contains the piezoelectric ceramic composition in which the Perovskite oxides expressed by General Formula 1 and the aluminum compound are contained in particular ratios. The sintering temperature is preferably in the range of from 1150 to 1300° C., and the sintering time is preferably in the range of from about 1 to 8 hours. The binder removal treatment and the calcination of the compact may be carried out successively and may be carried out separately.

In the polarization step, first, the sintered body is cut into a sheet form, and this sheet is surface-treated by lapping. The sintered body can be cut using a cutting machine such as a cutter, a slicer, or a dicing saw. After the surface treatment, temporary electrodes for the polarization treatment are formed on the opposite surfaces of the sheet-shaped sintered body. As a conductive material constituting the temporary electrodes, Cu is preferred since it can be easily removed by etching using ferric chloride. The temporary electrodes are preferably formed using vacuum deposition and sputtering.

A polarization electric field is applied to the sheet-shaped sintered body on which the temporary electrodes for the polarization treatment are formed, whereby a polarization treatment is carried out. In this way, a piezoelectric ceramic is obtained. The polarization treatment conditions are appropriately determined in accordance with the compositions of the piezoelectric ceramic composition contained in the sintered body. For example, the temperature of the sintered body subjected to the polarization treatment is controlled to be in the range of from 50 to 250° C., the application time of the polarization electric field is controlled to be in the range of from 1 to 30 minutes, and the magnitude of the polarization electric field is controlled to be 0.9 times or more than the coercive electric field of the sintered body. After the polarization treatment is carried out, the temporary electrodes formed on the surface of the sintered body are removed by etching or the like.

In the electrode forming step, first, the sintered body is cut into a desired element shape to form the piezoelectric substrate (piezoelectric ceramic) 11. The first and second vibrating electrodes 12 and 13 which are vibrating electrodes, the first and second lead electrodes 14 and 15, and the edge electrodes 16 and 17 are formed on the piezoelectric substrate 11, whereby the piezoelectric element 10 of the present embodiment can be obtained. The respective electrodes can be formed by vacuum deposition, sputtering, plating, and the like.

In the laminating step, the cavity layers 21 and 31, the sealing layers 22 and 32, the top board 20, and the base substrate 40 are prepared. These elements may be manufactured by a known method, and commercialized products may be used. For example, as for the cavity layers 21 and 31 and the sealing layers 22 and 32, a layer containing epoxy resin as its main component can be used. As for the top board 20 and the base substrate 40, a board or substrate containing alumina, steatite, forsterite, aluminum nitride, or mullite can be used. These elements are laminated in such an order as shown in FIG. 2, and as necessary, are bonded to each other using adhesive, whereby an assembly is obtained. After that, the terminal electrodes 41 to 43 are formed, and the oscillator 100 as shown in FIG. 1 can be obtained.

The ratios of metal elements in the piezoelectric substrate 11 provided in the oscillator 100 of the present embodiment are the same as the compounding ratios of the metal elements included in the starting raw materials. Therefore, by adjusting the compounding ratios of the starting raw materials, it is possible to obtain the piezoelectric substrate 11 having the sintered body (piezoelectric ceramic) with the desired compositions. This piezoelectric ceramic is made of the piezoelectric ceramic composition in which particles of Perovskite oxides and particles of the aluminum compound dispersed in grain-boundaries of the Perovskite oxide particles are contained in desired ratios. Since the piezoelectric substrate 11 which is a piezoelectric ceramic made of the piezoelectric ceramic composition having such compositions has a high Curie temperature, it can be used stably under a high-temperature environment. Moreover, since the above-described piezoelectric ceramic composition has a high frequency constant, it is possible to increase the thickness of the piezoelectric substrate 11. Furthermore, since the above-described piezoelectric ceramic composition has a high mechanical quality factor, excellent piezoelectric properties can be provided.

Hereinabove, the preferred embodiments of the piezoelectric ceramic composition, the piezoelectric ceramic, the piezoelectric element, and the oscillator of the present invention have been described. However, the present invention is not limited to the embodiments.

For example, the piezoelectric ceramic composition, the piezoelectric ceramic, and the piezoelectric element of the present invention may be used for products other than the oscillator, such as a filter, an actuator, an ultrasonic washing machine, an ultrasonic motor, an atomization vibrator, a fishfinder, a shock sensor, an ultrasonograph, a waste toner sensor, a gyro sensor, a buzzer, a transformer, or an ignition device. Moreover, the piezoelectric ceramic composition may constitute a sintered body and may be included in a calcined body obtained by the calcination and the granulated raw-material powder.

### EXAMPLES

The present invention will be described in more detail by way of examples and comparative examples. However, the present invention is not limited to the following examples.

(Preparation of Ceramic Samples 1 to 24)

In order to prepare Ceramic Samples 1 to 24, powders of lead oxide (PbO), titanium dioxide (TiO₂), manganese carbonate (MnCO₃), niobium oxide (Nb₂O₅), lanthanum hydroxide (La(OH)₃), strontium carbonate (SrCO₃), bismuth oxide (Bi₂O₃), and aluminum oxide (Al₂O₃, average particle size: 1.2 μm) were prepared as raw materials. These respective raw-material powders were weighed so that the piezoelectric ceramic compositions constituting the sintered ceramic samples (sintered bodies) have compositions of Ceramic Samples 1 to 24 as shown in Tables 1-1 and 1-2.

The respective weighed raw-material powders were mixed together in pure water for 2 to 16 hours by a ball mill using Zr balls, whereby slurry was obtained. This slurry was subjected to press molding after having been dried sufficiently and to calcination at 950° C. for 2 hours, whereby a calcined body was obtained. Subsequently, after finely grinding the calcined body by a ball mill, the fine powder was dried and granulated with an appropriately amount of PVA (polyvinyl alcohol) added as a binder. The obtained granulated powder was poured in an amount of about 3 g into a mold having dimensions of 20 mm long by 20 mm wide and subjected to molding at a load of 245 MPa using a unaxial press-molding machine. After the molded samples were subjected to heat treatment so as to remove the binder, the samples were calcined at temperatures ranging from 1200 to 1240° C. for 2 to 8 hours, whereby sintered bodies (Ceramic Samples 2 to 24) having the compositions shown in Tables 1-1 and 1-2 were prepared. The same operations were repeated to prepare a plurality of Ceramic Samples 1 to 24, and the following evaluations were conducted. It was confirmed through X-ray fluorescence analysis that the respective ceramic samples had the compositions shown in Tables 1-1 and 1-2. Moreover, it was confirmed through scanning electron microscope (SEM) observation that particles of the auxiliary component were dispersed in the grain-boundary regions of the particles of the main component shown in Tables 1-1 and 1-2. The aluminum compound of the auxiliary component was substantially Al₂O₃.

(Measurement of Sintered Body Density)

The prepared ceramic samples were processed into a flat board having a thickness of 0.23 mm using a double-sided lapping machine and cut into dimensions of 16 mm long by 15 mm wide using a dicing saw. The densities of the ceramic samples were calculated from the dimensions and masses of the cut ceramic samples. The calculation results are shown in Tables 1-1 and 1-2.

(Measurement of Curie Temperature)

The prepared ceramic samples were processed into a flat board having a thickness of 0.23 mm using a double-sided lapping machine and cut into dimensions of 6 mm long by 6 mm wide using a dicing saw. An Ag paste was vacuum-deposited to both ends of each of the cut ceramic samples, whereby an Ag electrode having dimensions of 5 mm by 5 mm was formed on the both ends. The ceramic samples having the Ag electrode formed thereon were placed in an electric furnace. Thereafter, the temperatures of the ceramic samples when the electrostatic capacitance of each ceramic sample reached a maximum during temperature increasing/decreasing processes were measured using an LCR meter, and an average of the temperatures was used as the Curie temperature Tc. The measurement results are shown in Tables 1-1 and 1-2.

(Measurement of Frequency Constant and Mechanical Quality Factor)

The prepared ceramic samples were processed into a flat board having a thickness of 0.23 mm using a double-sided lapping machine and cut into dimensions of 16 mm long by 15 mm wide using a dicing saw. An Ag paste was deposited to both ends of each of the cut ceramic samples, whereby a pair of temporary electrodes for the polarization treatment having dimensions of 15 mm by 15 mm was formed on both ends. The ceramic samples having the temporary electrodes formed thereon were placed in a silicone oil bath which was at a temperature of 120° C. A polarization electric field which is two times stronger than a coercive electric field was applied to the ceramic samples for 15 minutes, whereby a polarization treatment was carried out. After the polarization treatment was carried out, the temporary electrodes were removed, and the ceramic samples were polished again to a thickness of about 0.2 mm using a lapping machine and processed into test samples having dimensions of 7 mm by 4.5 mm using a dicing saw. Subsequently, a vibrating electrode made up of a Cr base layer having a thickness of 0.01 μm and an Ag layer provided on the Cr base layer were formed on both surfaces of each of the test samples using a vacuum deposition apparatus. In this way, samples (piezoelectric elements) for measuring the frequency constant (fr·t) and mechanical quality factor (Qₘₐₓ) were obtained.

The Qₘₐₓ values of the samples were measured in a 3rd-harmonic thickness extentional vibration mode around 30 MHz using an impedance analyzer (product of Agilent Technologies Corporation, product name: 4294A). The measurement results are shown in Tables 1-1 and 1-2. The Qₘₐₓ value represents the maximum value of Q(=tan θ, θ: phase angle (deg)) between a resonance frequency fr at which impedance becomes minimum and an antiresonance frequency fa at which impedance becomes maximum, and is one of the important properties of an oscillator and contributes to low-voltage driving properties.

Moreover, the resonance frequencies fr (Hz) of the samples at a room temperature were measured using the same impedance analyzer, and the frequency constants fr·t (Hz·m) were calculated from the product of the resonance frequency fr and the thickness t(m) (=2.3×10⁻⁴ (m)) of the piezoelectric element. The measurement and calculation results are shown in Tables 1-1 and 1-2.

TABLE 1-1

| | | | | | | | | | Auxiliary | | | | | |
|---|---|---|---|---|---|---|---|---|---|---|---|---|---|---|
| | | | | | | | | | Component | | | | | |
| Ceramic | Main Component | | | | | | | | Aluminum | Properties | | | | |
| Sample | (Pb_{α-β-γ-δ}La_{β}Sr_{γ}Bi_{δ})[Ti_{{1-(x+y+z)}}ZrₓMn_{y}Nb_{z}]O₃ | | | | | | | | Compound | Density | fr · t | Tc | | |
| No. | α-β-γ-δ | β | γ | δ | 1 − (x + y + z) | x | y | z | mass % | g/cm³ | Hz · mn | ° C. | Qmax | Remark |
| 1 | 0.94 | 0.040 | 0.010 | 0 | 0.792 | 0.10 | 0.036 | 0.072 | 0 | 7.66 | 7247 | 351 | 13.0 | Comp. Ex. |
| 2 | 0.94 | 0.040 | 0.010 | 0 | 0.792 | 0.10 | 0.036 | 0.072 | 3 | 7.56 | 7659 | 341 | 11.5 | Example |
| 3 | 0.94 | 0.040 | 0.010 | 0 | 0.792 | 0.10 | 0.036 | 0.072 | 5 | 7.43 | 7763 | 349 | 11.2 | Example |
| 4 | 0.94 | 0.040 | 0.010 | 0 | 0.792 | 0.10 | 0.036 | 0.072 | 7 | 7.33 | 8021 | 345 | 10.2 | Example |
| 5 | 0.95 | 0.040 | 0.010 | 0 | 0.792 | 0.10 | 0.036 | 0.072 | 5 | 7.48 | 7804 | 339 | 12.9 | Example |
| 6 | 0.95 | 0.040 | 0.010 | 0 | 0.792 | 0.10 | 0.036 | 0.072 | 9 | 7.21 | 8163 | 341 | 10.5 | Example |
| 7 | 0.95 | 0.040 | 0.010 | 0 | 0.792 | 0.10 | 0.036 | 0.072 | 11 | 7.10 | 8311 | 343 | 8.8 | Example |
| 8 | 0.95 | 0.040 | 0.010 | 0 | 0.792 | 0.10 | 0.036 | 0.072 | 13 | 7.00 | 8454 | 342 | 7.7 | Comp. Ex. |
| 9 | 0.96 | 0.040 | 0.010 | 0 | 0.792 | 0.10 | 0.036 | 0.072 | 5 | 7.41 | 7704 | 332 | 9.9 | Example |
| 10 | 0.93 | 0.040 | 0.010 | 0 | 0.792 | 0.10 | 0.036 | 0.072 | 5 | 7.40 | 7860 | 338 | 8.4 | Example |
| 11 | 0.94 | 0.045 | 0.005 | 0 | 0.792 | 0.10 | 0.036 | 0.072 | 5 | 7.41 | 7869 | 330 | 12.5 | Example |
| 12 | 0.90 | 0.040 | 0.050 | 0 | 0.792 | 0.10 | 0.036 | 0.072 | 5 | 7.30 | 7964 | 316 | 8.3 | Example |

In Table, mass % of auxiliary components represents the mass ratio of auxiliary components to main components.

TABLE 1-2

| | | | | | | | | | Auxiliary | | | | | |
|---|---|---|---|---|---|---|---|---|---|---|---|---|---|---|
| | | | | | | | | | Component | | | | | |
| Ceramic | Main Component | | | | | | | | Aluminum | Properties | | | | |
| Sample | (Pb_{α-β-γ-δ}La_{β}Sr_{γ}Bi_{δ})[Ti_{{1-(x+y+z)}}ZrₓMn_{y}Nb_{z}]O₃ | | | | | | | | Compound | Density | fr · t | Tc | | |
| No. | α-β-γ-δ | β | γ | δ | 1 − (x + y + z) | x | y | z | mass % | g/cm³ | Hz · mn | ° C. | Qmax | Remark |
| 13 | 0.92 | 0.020 | 0.050 | 0 | 0.792 | 0.10 | 0.036 | 0.072 | 5 | 7.24 | 7667 | 338 | 3.5 | Comp. Ex. |
| 14 | 0.93 | 0.050 | 0.010 | 0 | 0.792 | 0.10 | 0.036 | 0.072 | 7 | 7.24 | 8114 | 326 | 11.8 | Example |
| 15 | 0.92 | 0.070 | 0 | 0 | 0.810 | 0.10 | 0.030 | 0.060 | 7 | 7.16 | 8168 | 305 | 11.3 | Example |
| 16 | 0.90 | 0.100 | 0 | 0 | 0.792 | 0.10 | 0.036 | 0.072 | 7 | 7.21 | 7981 | 228 | 9.1 | Comp. Ex. |
| 17 | 0.95 | 0.050 | 0 | 0 | 0.910 | 0 | 0.030 | 0.060 | 7 | 7.25 | 7905 | 347 | 9.6 | Example |
| 18 | 0.94 | 0.040 | 0.010 | 0 | 0.842 | 0.05 | 0.036 | 0.072 | 7 | 7.34 | 7998 | 355 | 10.0 | Example |
| 19 | 0.94 | 0.040 | 0.010 | 0 | 0.812 | 0.08 | 0.036 | 0.072 | 7 | 7.31 | 8044 | 347 | 10.9 | Example |
| 20 | 0.94 | 0.040 | 0.010 | 0 | 0.652 | 0.24 | 0.036 | 0.072 | 7 | 7.23 | 7992 | 306 | 8.4 | Example |
| 21 | 0.94 | 0.040 | 0.010 | 0 | 0.592 | 0.30 | 0.036 | 0.072 | 7 | 7.15 | 7880 | 288 | 5.5 | Comp. Ex. |
| 22 | 0.94 | 0.040 | 0.010 | 0 | 0.780 | 0.10 | 0.040 | 0.080 | 7 | 7.22 | 8022 | 333 | 10.4 | Example |
| 23 | 0.81 | 0.030 | 0.100 | 0.02 | 0.850 | 0.10 | 0.020 | 0.030 | 1 | 7.47 | 7769 | 332 | 9.9 | Example |
| 24 | 0.69 | 0.000 | 0.250 | 0.02 | 0.950 | 0 | 0.020 | 0.030 | 0 | 7.41 | 8120 | 290 | 10.1 | Comp. Ex. |

In Table, mass % of auxiliary components represents the mass ratio of auxiliary components to main components.

According to the results shown in Tables 1-1 and 1-2, in the piezoelectric elements of the respective examples, Tc was 300° C. or higher, fr·t was 7600 Hz·m or higher, and Qₘₐₓ was 8 or higher.

(Preparation of Ceramic Samples 31 to 34)

A plurality of kinds of Al₂O₃ powders (average particle size ranging from 0.14 to 3.6 μm) having different average particle sizes was prepared as raw-material powders. Ceramic Samples 31 to 34 having the same compositions as Ceramic Sample No. 3 in Table 1-1 were prepared using this Al₂O₃ powder. The properties of the prepared Ceramic Samples 31 to 34 were measured similarly to Ceramic Sample No. 3. The measurement results are shown in Table 2.

(Measurement of Aluminum Compound Particle Size)

The prepared Ceramic Samples 31 to 34 were buried in a resin, and the surfaces of the respective ceramic samples were mirror-polished using a sandpaper and a diamond paste. A composition image of electrons reflected on the mirror-polished surface of each of the ceramic samples was captured using a scanning electron microscope (magnification: 3500). In the captured reflection electron composition image, the particle sizes of 50 aluminum compound particles were measured, and the maximum value (maximum particle size) thereof was calculated. The measurement results are shown in Table 2.

TABLE 2

| | Al₂O₃ | Properties of Ceramic Sample | | | | |
|---|---|---|---|---|---|---|
| | Powder | Maximum | | | | |
| | Average | Particle Size | | | | |
| Ceramic | Particle | of Aluminum | | | | |
| Sample | Size | Compound | Density | fr · t | | |
| No. | μm | μm | g/cm³ | Hz · m | Qmax | Remarks |
| 31 | 0.14 | 4.7 | 7.43 | 7850 | 10.5 | Example |
| 32 | 0.51 | 3.1 | 7.43 | 7783 | 11.3 | Example |
| 33 | 1.2 | 2.7 | 7.43 | 7763 | 11.2 | Example |
| 34 | 3.6 | 5.5 | 7.32 | 7865 | 11.9 | Example |

From the measurement results, it was confirmed that the larger maximum particle size of the aluminum compound particles in the ceramic samples provided higher fr·t values. However, when the maximum particle size was too large, Qₘₐₓ tends to decrease.

What is claimed is:

1. A piezoelectric ceramic composition comprising Perovskite oxides and an aluminum compound, the Perovskite oxides represented by General Formula (1):
(Pb_{α-β-γ-δ}M1_{β}M2_{γ}Bi_{δ})[Ti_{{1-(x+y+z)}}ZrₓMn_{y}Nb_{z}]O₃ (1)
wherein M1 represents at least one kind of element selected from the group consisting of La, Ce, Pr, and Nd, M2 represents at least one kind of element selected from the group consisting of Sr, Ca, and Ba, and α, β, γ, δ, x, y, and z satisfy the following numerical conditions:
0.96≦α≦1.01
0.03≦β≦0.07
0≦γ≦0.10
0≦δ≦0.02
0≦x≦0.24
0.02≦y≦0.04
0.03≦z≦0.08,
wherein the content ratio of the aluminum compound to the Perovskite oxides is from 1% by mass to 11% by mass.

2. A piezoelectric ceramic which has a sintered body made of the piezoelectric ceramic composition according to claim 1,
wherein the maximum particle size of the aluminum compound in the sintered body is equal to or smaller than 10 μm.

3. A piezoelectric element comprising the piezoelectric ceramic according to claim 2 and an electrode provided on the piezoelectric ceramic.

4. An oscillator comprising the piezoelectric element according to claim 3.
